(19) United States
(12) Patent Application Publication
(10) Pub. No.: US 2026/0251561 A1
(43) Pub. Date: Aug. 27, 2026

(54) DETECTION DEVICE HAVING PHOTODETECTOR ARRAY

(71) Applicant: National Taiwan University, Taipei (TW)

(72) Inventors: Ching-Fuh Lin, Taipei (TW); Yao-Han Dong, Taipei (TW)

(21) Appl. No.: 19/363,513

(22) Filed: Oct. 20, 2025

(30) Foreign Application Priority Data
Feb. 26, 2025 (TW) 114107022

(51) Int. Cl. G01N 21/3504; G01N 21/359; H10F 39/00

(52) U.S. Cl. CPC G01N 21/3504; G01N 21/359; H10F 39/8033

(57) ABSTRACT

A detection device includes a photodetector array composed of photodetectors, each of which includes a semiconductor substrate, a metal layer in contact with the upper surface of the semiconductor, a first electrode in contact with the upper surface of the metal layer, and a second electrode in contact with the lower surface of the semiconductor substrate. A response signal of the photodetector includes a photoelectric response signal and/or a photothermal response signal. As the energy of light source is insufficient to cross the Schottky energy barrier of the photodetector, the photodetector is locally thermal heated to result in the photothermal response signal, which is converted into a square wave signal.

### CROSS REFERENCE TO RELATED APPLICATIONS

The entire contents of Taiwan Patent Application No. 114107022, filed on Feb. 26, 2025, from which this application claims priority, are expressly incorporated herein by reference.

### BACKGROUND OF THE INVENTION

### 1. Field of the Invention

The present invention relates to a detection device having a photodetector array.

### 2. Description of Related Art

Infrared light detection had been used in many aspects, such as thermal imaging. Thermal imaging plays an important role in various fields, e.g., night vision applications and medical diagnosis. Conventional thermal detectors typically employs III-V semiconductor materials (e.g., InGaAs, HgCdTe, etc.) with excellent infrared light sensitivity and thermal conductivity as the substrate. However, these materials are expensive with complex manufacturing processes and are difficult to be highly integrated when arrayed over a large area.

Taiwan Patent Application No. 107116340 discloses a photodetector with metal/semiconductor junction. The photodetector detects infrared radiation with a different mechanism and could be made by simple process and low cost. In addition, different microstructure arrays may be fabricated on surface of the semiconductor, to enhance the surface plasmon effect and confine the incident light deep within the microstructure. The gradient cavity widths of the microstructure allow wavelengths of the incident light to generate a noticeable response signal through this mechanism.

Taiwan Patent Application No. 110145523 continues previous application by performing pre- and/or post-treatment, e.g., depositing an insulating layer between the metal and semiconductor interface, to reduce noise and improve the signal-to-noise ratio (SNR). The resulting photodetector has a response time of less than 10 microseconds.

### SUMMARY OF THE INVENTION

This summary is provided to introduce a selection of concepts in a simplified form that are further described below in the detailed description. This summary, and the foregoing background, is not intended to identify key aspects or essential aspects of the claimed subject matter. Moreover, this summary is not intended for use as an aid in determining the scope of the claimed subject matter.

In one aspect, a detection device for detecting a light is provided with a photodetector array, each of which includes a semiconductor substrate, a metal layer, a first electrode, and a second electrode. A lower surface of the metal layer forms a Schottky contact with an upper surface of the semiconductor substrate. A first electrode contacts an upper surface of the metal layer. A second electrode is in ohmic contact with a lower surface of the semiconductor substrate. Wherein the photodetector array converts the light into a response signal comprising a photoelectric response signal and/or a photothermal response signal, and the photodetector is locally heated to result in the photothermal response signal if energy of the light is insufficient to cross a Schottky barrier of the photodetector, and wherein the photodetector array further comprises a processor for converting the photothermal response signal into a square wave signal.

In one embodiment, wherein the response signal is a quasi-square wave signal (dominated by the photoelectric response signal). In one embodiment, wherein the response signal is a triangular wave signal, which is a response current-time signal, and the triangular wave signal is converted into a square wave signal, which is a response current slope-time signal. In one embodiment, the response signal of the photodetector that is reverse biased is greater than the response signal of the photodetector that is forward biased.

In one embodiment, per N data points of the triangular wave signal are subjected to a linear regression to obtain a response current slope, and the obtained response current slopes are plotted against time to obtain the square wave signal, and a fast response slope is obtained based on the square wave signal.

In one embodiment, wherein the square wave signal alternates between high response current slope levels and low response current slopes levels, and the fast response slope is obtained by subtracting an average slope of the high response current slope levels and an average slope of the low response current slope levels.

In one embodiment, the detection device is a thermal imaging device, and the response signal includes a photoelectric response signal and/or a photothermal response signal, and wherein the photoelectric response is a square wave signal, which is a response current-time signal, and the photothermal response signal is a triangular wave signal, which is a response current-time signal, and wherein the processor converts the triangular wave signal into a square wave signal, which is a response current slope-time signal, and the processor determines a temperature based on the response current slope-time signal. The photoelectric response signal is a square wave signal and does not require further conversion. In one embodiment, wavelengths of the light ranges from 2 μm to 15 μm. In one embodiment, the light is emitted from a light source, and the temperature of the light source is higher than ambient temperature. In one embodiment, the temperature of the light source ranges from 30° C. to 200° C.

The principle of the provided photodetector array is that mid-infrared incident light entering the Schottky junction is absorbed by the active layer of the photodetector and excites carriers that absorb the mid-infrared light. However, energy of the carriers is insufficient to cross the Schottky energy barrier to form a fast-response signal. The excited carriers will return to the their lowest energy level, ground state. During returning to the ground state, these excited electrons interact with the surrounding atoms or molecules, causing the energy distribution to change. A purpose is to detect the infrared light intensity by detecting these energy changes.

Advantages of the provided thermal imaging device:
1) An infrared light emitted from a light source is detected by detecting the energy change (photothermal response) of the photodetector caused by the infrared light, and then a detected signal is used to determine a temperature of the light source. And a linear fitting is used to convert a slow triangle wave response into a fast square wave response, so that the temperature can be determined immediately and accurately.
2) The thermal imaging device can be fabricated by a low cost silicon-based process, which is beneficial to integrate with other silicon-based components.
3) The thermal imaging device can detect wavelengths from visible light to mid-infrared light and temperatures from 35° C. to several hundred degrees. The thermal imaging device made of silicon-based components has advantages over other materials, e.g., indium arsenide (InAs) and mercury cadmium telluride (HgCdTe). First, silicon is one of the most mature materials in the semiconductor industry and has a complete manufacturing ecosystem for CMOS-MEMS. Compared with compound semiconductors e.g., HgCdTe, Si-based process is mature with widely available production equipment that can effectively reduce costs. In addition, silicon-based thermal imaging components could directly integrate with CMOS circuits on a single-chip (System on a Chip). This integration increases imaging speed, reduces power consumption and module size, and improves industry compatibility. Silicon-based materials have good chemical stability and mechanical strength, making them suitable for long-term applications. In addition, silicon has a low thermal expansion coefficient, which can reduce the impact of thermal stress on device life and increase reliability in harsh environments. Through mature CMOS processes, a large-area sensor or a high-resolution thermal imaging sensor array can be fabricates using the provided silicon-based thermal imaging technology. Conventional materials such as HgCdTe have difficulty maintaining uniformity in large-area processes.

In some embodiments, a detection device is configured to detect one or more target components in a gas sample. The detection device includes a gas chamber to fluid the gas sample. The light passes through the gas sample and is then received by the photodetector array to be converted into an electrical signal.

### BRIEF DESCRIPTION OF THE DRAWINGS

FIG. 1 shows a photodetector that is a thermal imaging device according to an embodiment of the present invention.

FIG. 2A shows a photodetector in accordance with an embodiment of the present invention.

FIG. 2B shows a photodetector in accordance with another embodiment of the present invention.

FIG. 3 shows a measurement system for measuring the photodetector of the present invention.

FIG. 4 shows a method of converting a triangle wave signal of the provided photodetector into a square wave signal.

FIG. 5 shows a response current vs light source temperature bar graph of a photodetector having an inverted pyramid array, wherein the light source temperature is controlled between 30 to 40 degrees C. with one degree increment, and per 50 data points are taken to convert the measured triangle wave signal into a square wave signal.

FIG. 6 shows a response current vs light source temperature bar graph of the planar photodetector (Planar) and the photodetector having the inverted pyramid array (IPS).

FIGS. 7A and 7B are raw response current vs time (slow response) plots of the planar photodetector described in FIG. 2A measured at light source temperatures between 35 to 42 degrees C. with 0.2-degree increment.

FIGS. 8A and 8B show the fast response converted from the slow response shown in FIGS. 7A and 7B.

FIG. 9 shows a response current per unit time (response current slope) vs light source temperature bar graph of the planar photodetector described in FIG. 2A, wherein the light source temperature is controlled between 35 to 42 degrees C. with 0.2-degree increment.

FIGS. 10A and 10B are raw response current vs time (slow response) plots of the photodetector described in FIG. 2B measured at light source temperatures between 35 to 42 degrees C. with 0.2 degree increment.

FIGS. 11A and 11B show the fast response converted from the slow response shown in FIGS. 10A and 10B, wherein per 50 data points are taken to convert the measured triangle wave signal into a square wave signal.

FIG. 12 shows a response current per unit time (response current slope) vs light source temperature bar graph of the photodetector described in FIG. 2B, wherein the light source temperature is controlled between 35 to 42 degrees C. with 0.2-degree increment.

FIG. 13 shows a response current per unit time (response current slope) vs light source temperature scatter plots of the planar photodetector (Planar) and the photodetector having the inverted pyramid array (IPS), wherein the data are taken from FIGS. 9 and 12 and linear fits are performed using a two-variable linear equation.

FIGS. 14A-14D show a detection device composed of an photodetector array for detecting one or more target components in a gas sample according to some embodiments of the present invention.

FIG. 15 shows a detection device composed of an photodetector array for detecting one or more target components in a gas sample according to another embodiment of the present invention.

FIG. 16 shows a detection device composed of an photodetector array for detecting one or more target components in a gas sample according to another embodiment of the present invention.

FIGS. 17A and 17B are raw response current vs time (slow response) plots of the photodetector described in FIG. 2B measured at different light source temperatures, wherein the photodetector is applied with −0.3 V bias voltage and the light source temperature is controlled between 35 to 42 degrees C. with 0.1 degree increment.

FIGS. 18A and 18B show the fast response converted from the slow response shown in FIGS. 17A and 17B.

FIG. 19 shows a response current per unit time (response current slope) vs light source temperature line graph of the photodetector described in FIG. 2B, wherein all data are taken from FIGS. 18A and 18B.

### DETAILED DESCRIPTION OF THE PREFERRED EMBODIMENT

Embodiments of the invention are now described and illustrated in the accompanying drawings, instances of which are to be interpreted to be to scale in some implementations while in other implementations, for each instance, not. In certain aspects, use of like or the same reference designators in the drawings and description refers to the same, similar or analogous components and/or elements, while according to other implementations the same use should not. According to certain implementations, use of directional terms, such as, top, bottom, left, right, up, down, over, above, below, beneath, rear, front, clockwise, and counterclockwise, are to be construed literally, while in other implementations the same use should not. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components may be greater or less than that disclosed, except where expressly restricting the amount of the components.

Taiwan Patent Application No. 10711634 disclosed various photodetectors wherein a surface of the silicon substrate that facing the metal is planar or patterned to form an inverted pyramid array. This application and all published documents discussed in this text are fully incorporated by reference as if fully set forth herein. Some embodiments of the present invention provide a detection device having a photodetector array, which includes a plurality of photodetectors. Each photodetector includes a semiconductor substrate (e.g., Si) and a metal layer deposited on the semiconductor substrate, and a surface of the semiconductor substrate facing the metal layer is planar or patterned to form a microstructure array (including one or more microstructures, such as an inverted pyramid array including one or more inverted pyramids). Each photodetector further includes a first electrode and a second electrode. A lower surface of the metal layer forms a Schottky contact with an upper surface of the semiconductor substrate. The first electrode contacts an upper surface of the metal layer. The second electrode forms an ohmic contact with a lower surface of the semiconductor substrate. The response signal of the photodetector may include a photoelectric response and a photothermal response. If energy of incident light is insufficient to cross the Schottky barrier of the photodetector, the photodetector will be locally heated and hence generates a photothermal response. By analyzing an infrared spectrum obtained by the photodetector array, the detection device can be used for gas detection (e.g., VOCs breathalyzer analysis, environmental gas analysis), blood sugar measurement, food composition analysis, etc. The photodetector array can also be used for thermal imaging. The light incident to the photodetector array could be a light emitted by an object to be detected, or it can be a transmitted light or reflected light irradiated by an infrared light on the object to be detected. One or more light-splitting and directing devices, such as but not limited to one or more gratings, mirrors, filters, and/or lenses, may be arranged between the incident light and the object to be detected, to split the incident light and focus the separated light of different wavelengths on the corresponding one or more photodetectors of the photodetector array. In one embodiment, the photodetector array detects multiple incident lights simultaneously.

For the sake of convenience, the following embodiment illustrates that the provided photodetector array is applied to a thermal imaging device.

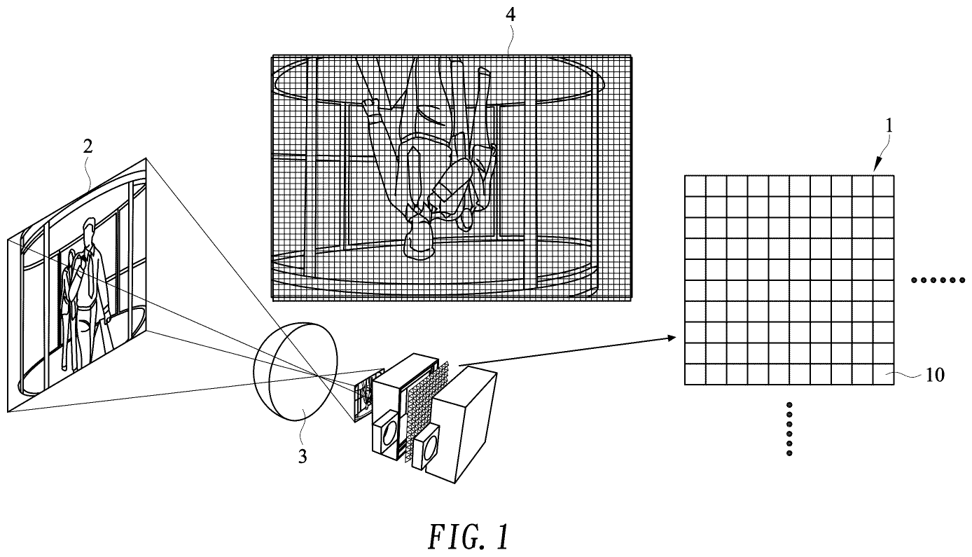

As shown in FIG. 1, one embodiment of the present invention provides a thermal imaging device comprising a photodetector array 1 for detecting an infrared radiation emitted by an object 2 (including a human body, an animal, or an object). An optical path device 3 for filtering and/or focusing the infrared radiation may be provided between the object 2 and the photodetector array 1. Furthermore, the thermal imaging device may include a back-end integration module 4 connected to the photodetector array 1 to process the detection signal.

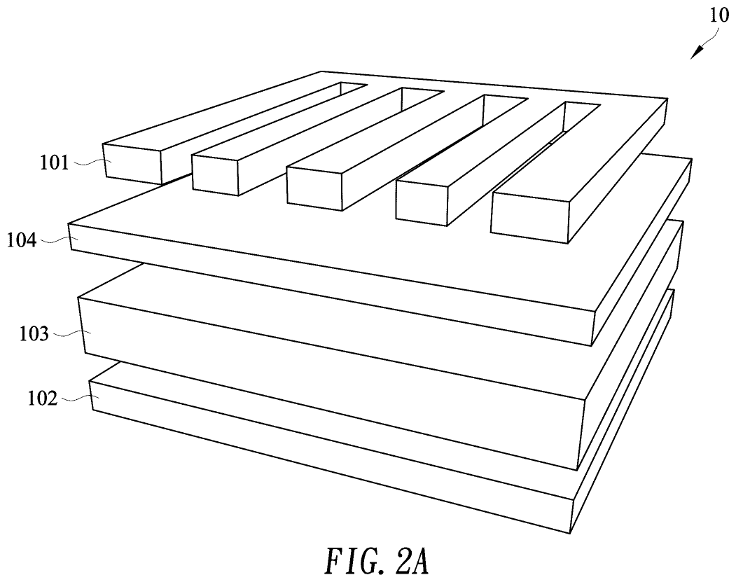

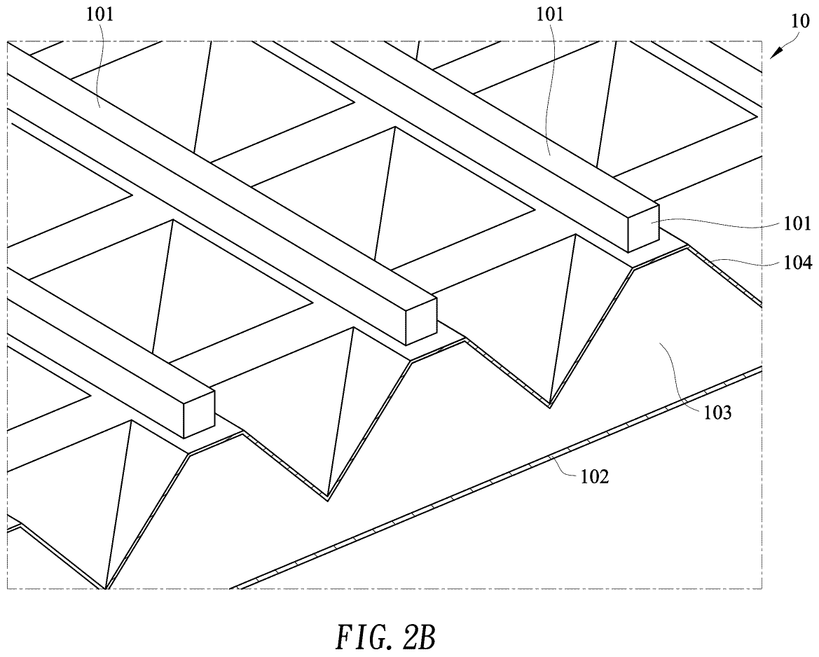

In some embodiments, the photodetector array 1 consists of photodetectors 10 as shown in FIG. 2A, which includes a semiconductor substrate 103, a metal layer 104, a first electrode 101, and a second electrode 102. In which, a lower surface of the metal layer 104 forms a Schottky contact with an upper surface of the semiconductor substrate 103. The first electrode 101 contacts an upper surface of the metal layer 104. The second electrode 102 forms an ohmic contact with a lower surface of the semiconductor substrate 103.

In some embodiments, the photodetector array 1 consists of photodetectors 10 as shown in FIG. 2B. The photodetectors 10 described in FIG. 2B is similar to the photodetectors 10 described in FIG. 2A, except that the upper surface of the semiconductor substrate 103 is patterned to form an inverted pyramid array including one or more inverted pyramids.

In a preferred embodiment, the semiconductor substrate 103 in FIG. 2A and FIG. 2B is an n-type silicon substrate, the metal layer 104 and the first electrode (finger electrode) 101 are made of silver, and the second electrode 102 is made of aluminum.

The following describes an example of fabricating a photodetector 10 described in FIG. 2A and a photodetector 10 described in FIG. 2B.

A double-polished n-type silicon substrate with thickness of 600-610 μm and resistance of 2-70 cm was used. A diamond knife was used with an iron clamp to cut the silicon substrate into squares approximately 2.5 cm×2.5 cm in size. The silicon substrate was ultrasonically cleaned sequentially with acetone, isopropyl alcohol (IPA), and deionized water (DI water), with each cleaning step lasting approximately 10 minutes.

A SiO₂ layer with a thickness of approximately 600 nm was then deposited on the silicon substrate using plasma chemical vapor deposition (PECVD). HMDS was then spin-coated using a spin coater at an initial speed of 1000 rpm for 10 seconds, followed by a final speed of 4000 rpm for 40 seconds. A negative photoresist ENPI-307 was then spin-coated using the spin coater at an initial speed of 1000 rpm for 10 seconds, followed by a final speed of 4000 rpm for 40 seconds. When spin-coating the negative photoresist, the negative photoresist was dropped onto the substrate and allowed to stand for 5-10 seconds to fully spread over the substrate. The spin-coated substrate was placed on a heating plate and soft-baked at 110° C. for 3 minutes.

The silicon substrate was then exposed and developed using an exposure machine for 20 seconds, followed by a post-exposure bake at 130° C. for 2 minutes. Develop with MF-319 developer (approximately 40 seconds) and inspect the pattern using an optical microscope. After confirmation, the pattern was hard baked at 130° C. for 3 minutes.

Dry etching was then performed using reactive ion etching (RIE) with the following parameters: etching SiO₂, CHF₃: 30 sccm, pressure: 1.3 Pa, RF power: 90 W, for 30 minutes. Etching photoresist (PR), O₂: 50 sccm, pressure: 13.3 Pa, RF power: 100 W, for 25 minutes.

To fabricate an inverted pyramid array on surface of the silicon substrate, wet etching is used with the following steps: (1) heat KOH solution to 75° C. using a heating stage (with temperature controlled between 150° C. and 180° C.); (2) immerse the silicon substrate in the KOH solution to etch for approximately 15 minutes (it is recommended to start with 10 minutes, but longer may be required); then remove the silicon substrate, rinse it with pure water, and blow dry it. Observe the resulting pattern using the optical microscope. The silicon substrate was then immersed in a buffered oxide etchant (BOE) solution for five minutes to remove silicon dioxide (SiO₂) on the surface. Then clean the silicon substrate with pure water.

An aluminum layer with a uniform thickness of 100 nm (to serve as back electrode) was then deposited on the bottom surface of the silicon substrate using a thermal evaporation machine at a deposition rate of 1 Å/s.

A silver layer with a thickness of 10 nm was deposited on the upper surface of the silicon substrate using the thermal evaporation machine at a deposition rate of 0.1 Å/s. This silver layer will serve as an active layer responsible for converting light into electricity in the device.

Finally, a silver finger-shaped electrode with a total thickness of 100 nm was deposited on the active layer continuously at deposition rates of 0.1 Å/s (10 nm), 0.3 Å/s (10 nm), 0.5 λ/s (10 nm), and 1 Å/s (10 nm).

If rapid thermal annealing (RTA) is required, the resulted photodetector is placed in an RTA machine and subjected to RTA according to the specific parameters required.

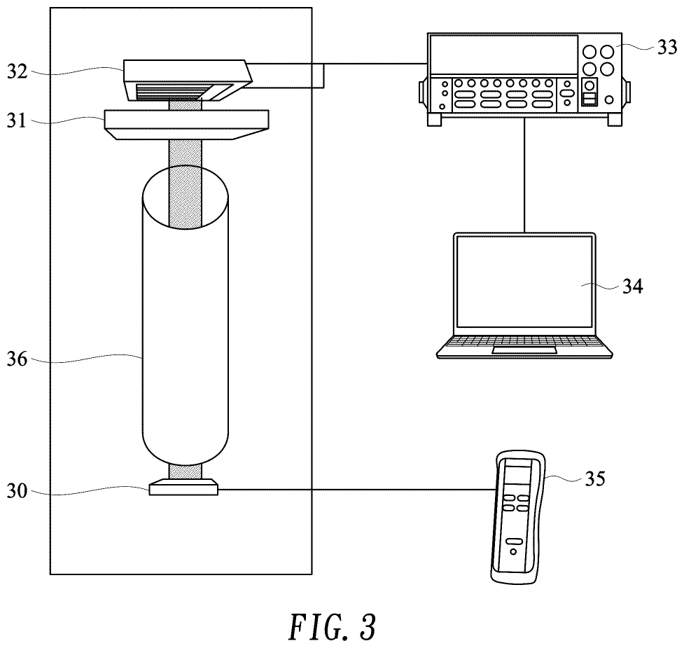

FIG. 3 shows a measurement system for measuring properties of the fabricated photodetectors according to the present invention. Referring to FIG. 3, the measurement system includes a light source 30, a chopper 31, a device under test 32, a multifunction source meter 33 (Keithley 2400), and a computer 34. Device under test 32 is the photodetector 10 shown in FIG. 2A or FIG. 2B. Depending on the desired emission wavelength band, light source 30 can be a ceramic heater that is electrically heated to produce blackbody radiation. A thermocouple 35 can be used to monitor the temperature of light source 30. In some experiments, light source 30 is a thermoelectric cooler connected to a temperature controller (not shown) to output low-temperature blackbody radiation. Chopper 31 periodically interrupts the emitted infrared radiation at a constant chopping interval, e.g., 5-10 seconds “on” (allowing light to pass) and 5-10 seconds “off” (block light to pass), to generate a signal with an on-off cycle of 10-20 seconds. FIG. 3 shows the measurement system vertically arranged. Some experiments of the present invention are carried out in the same measurement system while the light source 30 and the device under test 32 are horizontally arranged, that is, the light source 30 and the device under test 32 are at the same level. In addition, a reflective tube 36 may be provided between the chopper 31 and the light source 30. In addition, a reflector may be provided behind the light source 30 to enhance the luminous intensity. Furthermore, a monochromater may be provided between the chopper 31 and the device under test 32 to split the light before it enters the device under test. The distance between the device under test 32 and the light source 30 is about 2 to 10 centimeters. The device under test 32 converts the light into an electrical signal that is received by the multifunction source meter 33 (Keithley 2400) and then transmitted to the computer 34 for processing. The measurement system is preferably covered with a box to prevent light leakage.

In one embodiment, a planar photodetector as described in FIG. 2A with 0.1 volt bias was measured by the horizontal-arranged measurement system, in which the light source 30 is heated to 200-degree C. to generate blackbody radiation. It was observed that the response of the planar photodetector was a square wave signal, and the top and bottom of the square wave signal increased or decreased over time. In fact, the photodetector converts the incident light into two response signals simultaneously. Wen et al. divided these response signals into photoelectric (PE) and photothermal (PT) responses. The former is a rapid response generated by the photodetector as the light passing through the chopper 31. The latter is a current signal that changes over time when the photodetector is continuously illuminated in a periodical manner. Experiments have found that the produced photodetectors of this invention also exhibit fast and slow responses under applied bias. Under forward biased, the photothermal (PT) response and the photoelectric response (PE) operate in opposite directions, but their response times differ. The photoelectric (PE) response is an extremely fast and a directional signal, while the photothermal (PT) response is a slower process involving light-to-heat conversion.

Table 1 lists the response signals of a provided planar photodetector under different bias voltages (0.1, 0.2, and 0.3 volts) and varying light source temperatures. As can be seen from Table 1, a fast response is very pronounced with only a slight inclination at the top and bottom of the square wave as the photodetector is forward biased by 0.1 volt and the light source is heated to 200 degrees. When the light source is reduced to 150 degrees C., the proportion of the fast response decreases significantly, the top and bottom inclinations of the square wave increase dramatically, and the slow response becomes more prominent than the fast response. When the light source temperature drops to 100 degrees, the fast response disappears completely and is replaced by a triangle wave signal. This indicates that as the light source temperature decreases, the photoelectric (PE) response signal gradually decreases and is mainly dominated by the photothermal (PT) response. Such changes are also observed when a bias of 0.2 or 0.3 volts is applied.

Referring to Table 1, when the light source temperature is fixed at 200 degrees, the fast response (square wave signal) is obvious at a bias of 0.1 volt. As the bias increases to 0.2 volts, the proportion of the slow response increases. When the bias increases to 0.3 volts, the proportions of the slow response and the fast response are approximately equal. The trend caused by bias voltage changes are similar to those caused by light source temperature changes, but the mechanisms are different. Under the same bias, the distance between the highest and lowest points of the response current gradually decreases as the light source temperature decreases, which means that the photoelectric response decreases as the light source temperature decreases. The photoelectric response decreases indicates that the number of hot carriers that directly cross the energy barrier decreases. As the light source temperature gradually decreases, the photoelectric response gradually decreases and finally only the slow response signal remains.

The following mechanism may explain the experimental results. When applying a reverse bias to the photodetector, the dark current is small and has little effect on the current response. When applying a forward bias to the photodetector, a current flows through the photodetector to affect the photodetector by local heating effect, causing electrical properties of the photodetector (e.g., series resistance and Schottky barrier) to change, thereby producing a triangular wave photothermal response. Applying a forward bias to the photodetector will increase the photothermal response. In addition, the light intensity decreases as the light source temperature decreases, leading to decrease in the photoelectric response. Finally, the photothermal response dominates the response signal. The incident light excites the metal to generate hot carriers, which are thermally diffused to the Schottky interface. With an applied bias, carriers that do not pass through the barrier accumulate in the metal and heat the interface, causing changes in the interface's electrical properties and generating a photothermal (PT) response current. The direction of the photothermal response current is the same as the applied bias.

The voltage-current (I-V) curves of the planar photodetector at different temperatures were then measured and fitted using the formula for thermionic emission. Table 2 summarizes the results.

TABLE 2

| Temp (º C.) | series resistance (Q) | Schottky barrier (eV) |
|---|---|---|
| 26 | 53.09488 | 0.5402 |
| 25.8 | 52.44873 | 0.54026 |
| 25.6 | 51.62679 | 0.54032 |
| 25.4 | 50.75333 | 0.54034 |
| 25.2 | 50.4008 | 0.54049 |

As shown in Table 2, the series resistance and energy barrier height of the photodetector increase and decrease, respectively, as the temperature increases.

In the horizontal-arranged measurement system, the photodetector is only affected by thermal radiation. In the vertical-arranged measurement system, in addition to thermal radiation, the local heating effect of the photodetector could be more obvious due to thermal convection.

In one embodiment, using the horizontal-arranged measurement system, a provided planar photodetector was tested at different light source temperatures with a 0.1V bias applied to the photodetector. The experimental results show that at a light source temperature of 200 degrees, the photoelectric response is clear. At 150 degrees, although the noise increases, one can clearly identify the response signal. When the light source temperature drops to 135 degrees, the response signal begins to become less obvious and gradually becomes unrecognizable. At 120 degrees, no signal can be observed. The experimental results reveal that a cut-off temperature of the planar photodetector is approximately 135 degrees. On the other hand, the same experiments were conducted in the vertical-arranged measurement system. And the results show that, at the light source temperature of 150° C., the photoelectric response remains clear with reduced noise compared to measurements using the horizontal-arranged measurement system. Furthermore, the response signal is still clearly observable at a light source temperature of 100° C. Even at 50° C., a weak signal can still be observed. Compared to the horizontal-arranged measurement system, the vertical-arranged measurement system significantly improves measurement sensitivity and the cut-off temperature.

Table 3 shows response currents of the planar photodetector (FIG. 2A) at different light source temperatures with a constant 0.3V bias applied (measured using a vertical-arranged measurement system). As the light source temperature decreases, the response current decreases. A clear triangular wave signal can be observed at 100° C. and 50° C. Then gradually lower the temperature by 10 degrees, pronounced responses can be observed between 40° C. and 30° C. The signal is generated until the light source is turned off and cooled to room temperature.

Table 4 shows response currents of the photodetector described in FIG. 2B at different light source temperatures with a constant 0.3V bias applied (measured using the vertical-arranged measurement system). As shown in Table 4, a clear triangular wave signal can be observed at both 100 and 50 degrees of the light source. Then gradually lower the temperature by 10 degrees, although noise gradually becomes more pronounced between 40 and 30 degrees, a clear triangular wave signal is still visible. The signal is generated until the light source is turned off and cooled to room temperature. Compared to planar photodetector, response signals of photodetector with the inverted pyramid array exhibit more noise

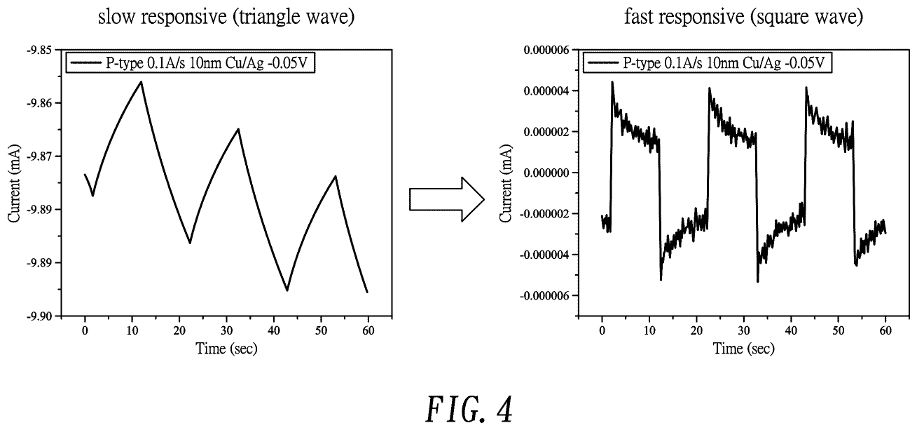

In one embodiment continuing with Tables 3 and 4, a constant 0.3V bias voltage was applied to planar and inverted pyramid photodetectors as described in FIGS. 2A and 2B, respectively, and measurements were taken in 2-degree decrements between 40° C. and 30° C. As the temperature decreased, the response current decreased accordingly. Although response signals of 2° C. decrements can be observed, significant noise affected the resolution of the temperature detection. Furthermore, the on-off cycle of the chopper affects the response current. Therefore, an attempt was made to address this issue by analyzing the instantaneous slope of the triangle wave. Slope analysis is unaffected by the on-off cycle of the chopper. This method extracts a slope of an original data point and its adjacent points, then averages these slopes to convert them into a new signal. As shown in FIG. 4, a slow responsive triangle wave on the left is converted to a fast responsive square wave on the right by using the slope analysis. The slope analysis produces a stable signal that is unaffected by the on-off cycle, thereby improving the resolution of quantitative analysis in temperature. In a preferred embodiment, linear regression is used for signal transformation. In one embodiment, per number (e.g., 10, 20, 30, 40, or 50) of data points of a triangular wave are used to determine a slope by the linear regression, and the determined slopes are plotted against time to form a new signal. The slope of a regression line minimizes the sum of squared residuals between the observed data points and the regression line. These slopes are found using the least squares method. Before transformation, the response currents are plotted against time, and after transformation, the linear regression slopes (response current per unit time) are plotted against time.

One embodiment employs a linear regression model: Y=β₀+β₁X+ε

Where Y denotes the dependent variable, X denotes the independent variable, β₀ denotes the intercept, β₁ denotes the slope, and ε denotes the error term.

The goal is to find β₀ and β₁ that minimize the sum of squared residuals. Define the residual eᵢ as the difference between the observed value Yᵢ and the predicted value. i, eᵢ=Yᵢ−Ŷᵢ

The predicted value Ŷᵢ can be obtained through the regression equation: Ŷᵢ=β₀+B₁Xᵢ

The goal is to minimize the sum of squared residuals for all observed values, that is:

$$Minimize {\sum }_{i = 1}^{n} {e}_{i}^{2} = {\sum }_{i = 1}^{n} {( {Y}_{i} - {\hat{Y}}_{i} )}^{2}$$

Substituting Yᵢ into the equation to obtain:

$${\sum }_{i = 1}^{n} {( {Y}_{i} - {β}_{0} - {β}_{1} {X}_{i} )}^{2}$$

Now, find β₀ and β₁ that minimize this equation.

To find β₀ and β₁, minimize this equation by taking the derivatives with respect to β₀ and β₁, respectively, and setting them to zero. Taking the derivative with respect to β₀:

$$\frac{\partial }{\partial {β}_{0}} {\sum }_{i = 1}^{n} {( {Y}_{i} - {β}_{0} - {β}_{1} {X}_{i} )}^{2} = - 2 {\sum }_{i = 1}^{n} {X}_{i} ( {Y}_{i} - {β}_{0} - {β}_{1} {X}_{i} ) = 0$$

Taking the derivative with respect to β₁:

$$\frac{\partial }{\partial {β}_{1}} {\sum }_{i = 1}^{n} {( {Y}_{i} - {β}_{0} - {β}_{1} {X}_{i} )}^{2} = - 2 {\sum }_{i = 1}^{n} {X}_{i} ( {Y}_{i} - {β}_{0} - {β}_{1} {X}_{i} ) = 0$$

Solving these two equations can obtain β₀ and β₁ that minimize the sum of squared residuals.

B₁ is used as the slope and all data points of the triangular wave signal are converted into linear regression slopes using this method. The obtained slopes are then plotted against time to form a new signal. Table 5 shows the original triangular wave signal (0 data points) and new signals converted by the linear regression wherein per number (10, 20, 30, 40, or 50) of data points of the triangular wave are used to determine a slope, and wherein the triangular wave is response current vs time plot of a 0.3V biased photodetector having inverted pyramid (IPS) array measured at fixed light source temperature of 30° C.

As shown in Table 5, as the number of sampling (data) points increases, the noise of the converted signal decreases and the signal become more distinct. The converted signal becomes recognizable as the number of sampling points reaches 50. The number of sampling points is not limited.

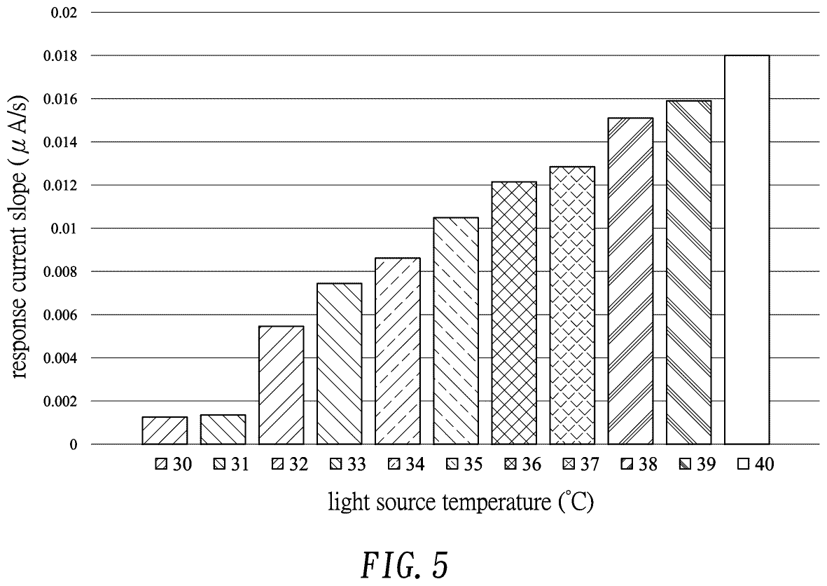

FIG. 5 shows a response current vs light source temperature bar graph of a photodetector having an inverted pyramid array, wherein the photodetector is measured using the vertical-arranged measurement system, the light source temperature is controlled between 30 to 40 degrees C. with one degree increment, and per 50 data points are taken to convert the measured triangle wave signal into a square wave signal. The square wave signal alternates between high response current levels and low response current levels, and in the bar graph, the magnitude of response current slope is obtained by subtracting an average slope of the high response current slope levels and an average slope of the low response current slope levels. It can be clearly observed from FIG. 5 that the response current increases with the increase of the light source temperature.

In addition, the raw data points (response currents) of the photodetector described in FIG. 2B and the planar photodetector described in FIG. 2A are compared, wherein both photodetectors are applied with 0.1V bias voltage and the response currents are measured using the vertical-arranged measurement system with different light source temperatures. The experimental results show that at the same light source temperature, the response current of the photodetector having inverted pyramid array is significantly larger, and its response current is more obvious after applying a bias of 0.1V. When the light source temperature is 50 degrees and no bias voltage is applied, the response of the planar photodetector is unrecognizable, while the signal of the photodetector with inverted pyramid array still observable. The results indicate that the photodetector with inverted pyramid array is more susceptible to local heating effects.

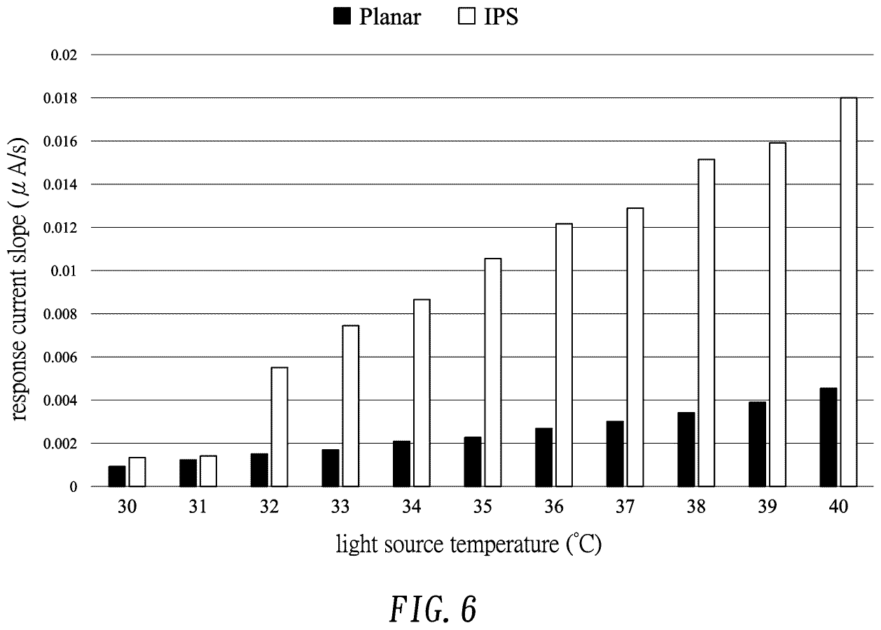

FIG. 6 shows a response current vs light source temperature bar graph of the planar photodetector (Planar) and the photodetector having the inverted pyramid array (IPS), wherein both photodetectors are applied with 0.1V bias voltage and measured using the vertical-arranged measurement system, the light source temperature is controlled between 30 to 40 degrees C. with one degree increment, and per 50 data points are taken to convert the measured triangle wave signal into a square wave signal. As shown in FIG. 6, the response current can be effectively compared after converting the slow response to a fast response. The response current of both photodetectors increases with the increase of the light source temperature, and the photodetector having the inverted pyramid array (IPS) reveals a larger response.

### Confirmation of Minimum Sensitivity in Temperature Measurement

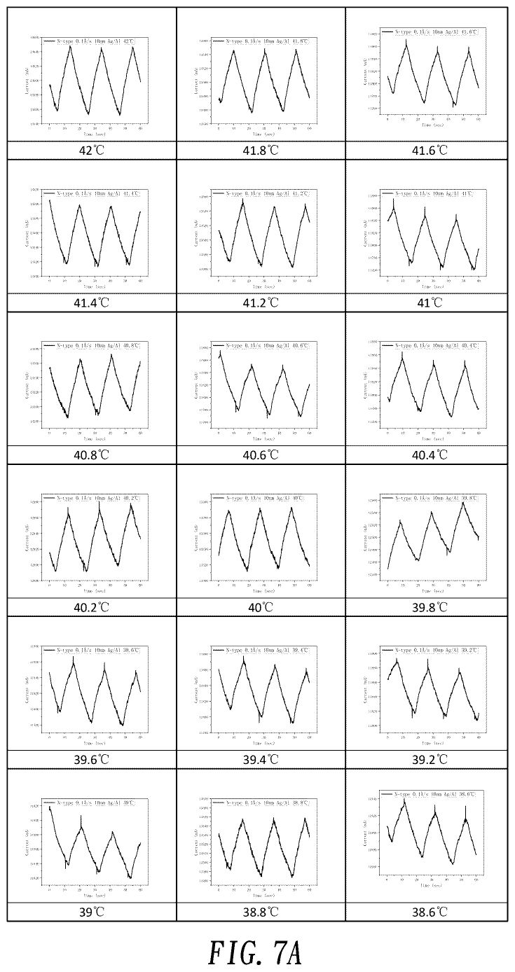

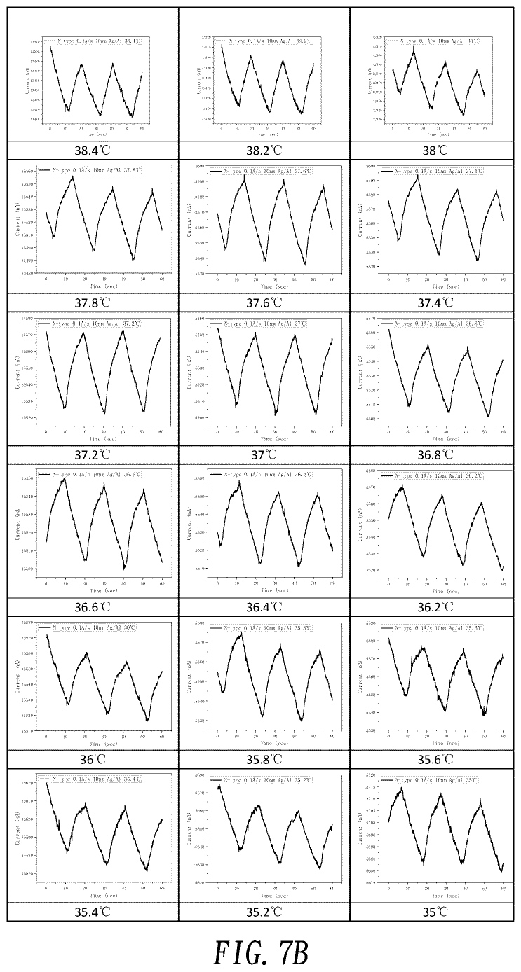

FIGS. 7A and 7B are raw response current vs time (slow response) plots of the planar photodetector described in FIG. 2A measured at different light source temperatures, wherein the planar photodetector is applied with 0.1 V bias voltage and is 2 cm away from the light source, the chopper has a ON period of 10 second and an OFF period of 10 second, and the light source temperature is controlled between 35 to 42 degrees C. with 0.2 degree increment.

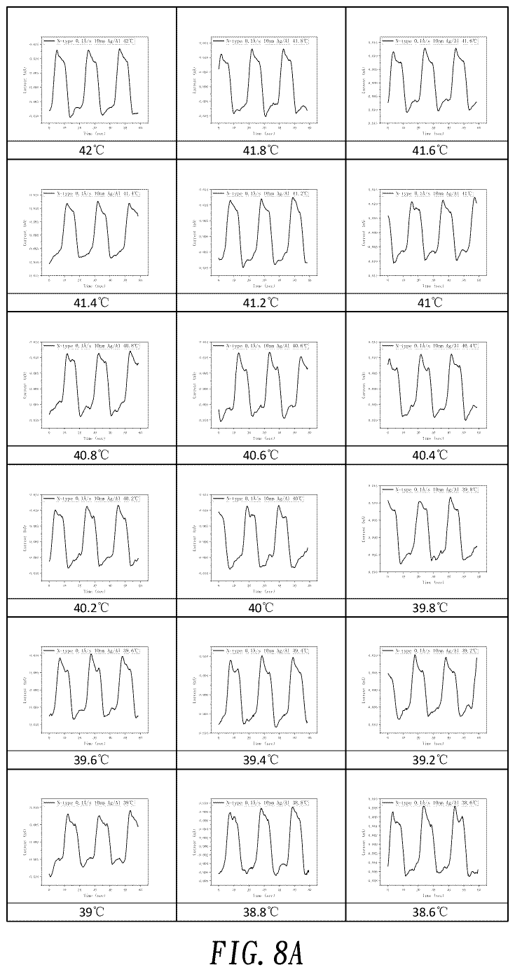

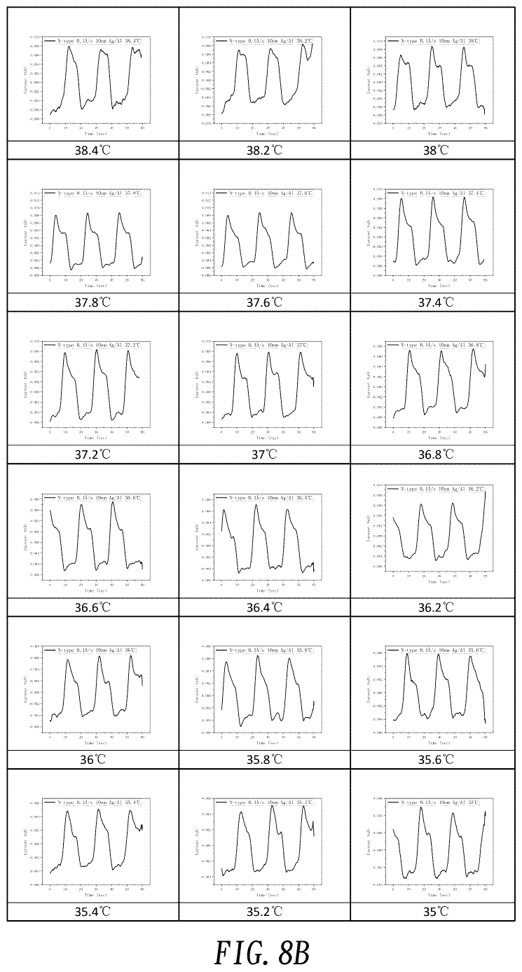

FIGS. 8A and 8B show the fast response converted from the slow response shown in FIGS. 7A and 7B, wherein per 50 data points are taken to convert the measured triangle wave signal into a square wave signal.

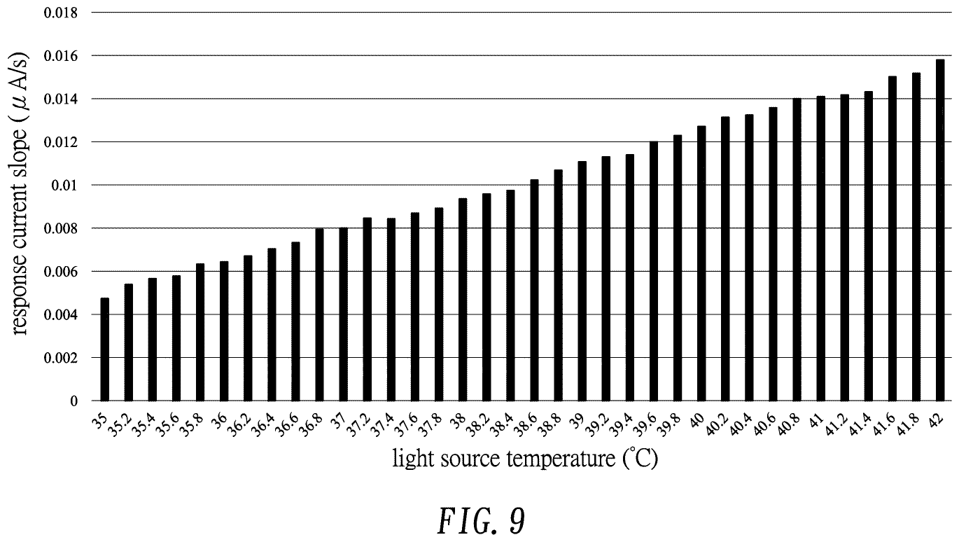

FIG. 9 shows a response current per unit time (response current slope) vs light source temperature bar graph of the planar photodetector described in FIG. 2A, wherein the planar photodetector is applied with 0.1 V bias voltage and is 2 cm away from the light source, the chopper has a ON period of 10 second and an OFF period of 10 second, the light source temperature is controlled between 35 to 42 degrees C. with 0.2 degree increment, and per 50 data points are taken to convert the measured triangle wave signal into a square wave signal. The square wave signal alternates between high response current slope levels and low response current slope levels, and in the bar graph, the magnitude of response current slope is obtained by subtracting an average slope of the high response current slope levels and an average slope of the low response slope current levels.

As shown in FIG. 9, the response current per unit time (response current slope) of the planar photodetector decreases as the light source temperature decreases. This demonstrates that the planar photodetector described in FIG. 2A has a measuring accuracy of 0.2° C.

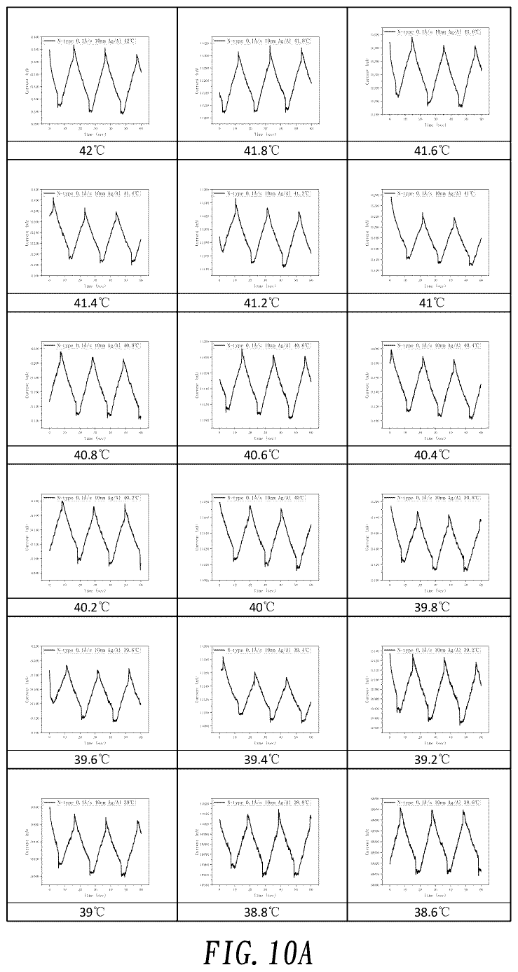

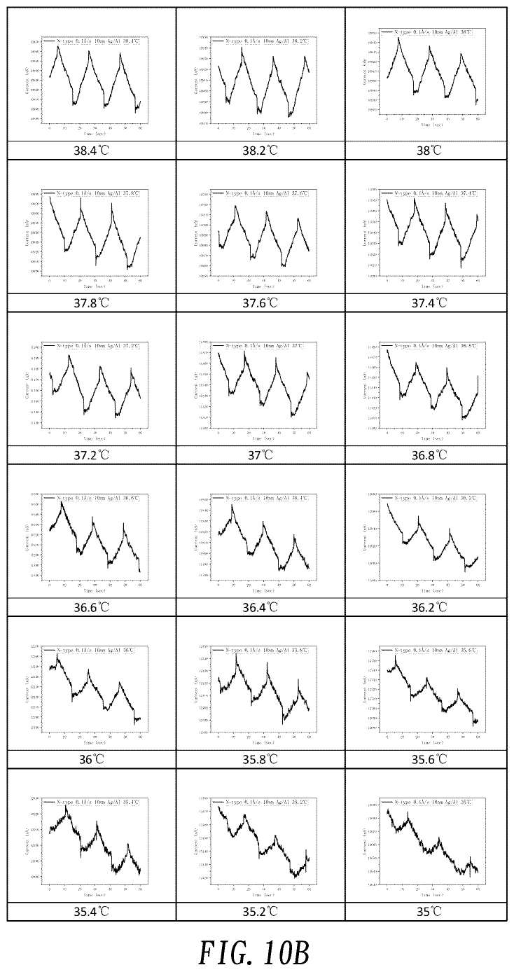

FIGS. 10A and 10B are raw response current vs time (slow response) plots of the photodetector described in FIG. 2B measured at different light source temperatures, wherein the photodetector having the inverted pyramid array (IPS) is applied with 0.1 V bias voltage and is 2 cm away from the light source, the chopper has a ON period of 10 second and an OFF period of 10 second, and the light source temperature is controlled between 35 to 42 degrees C. with 0.2 degree increment.

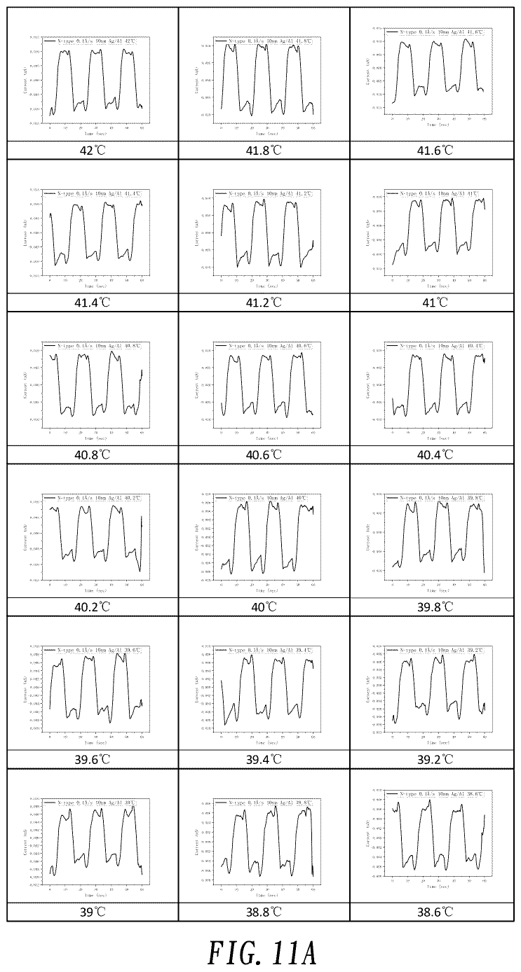

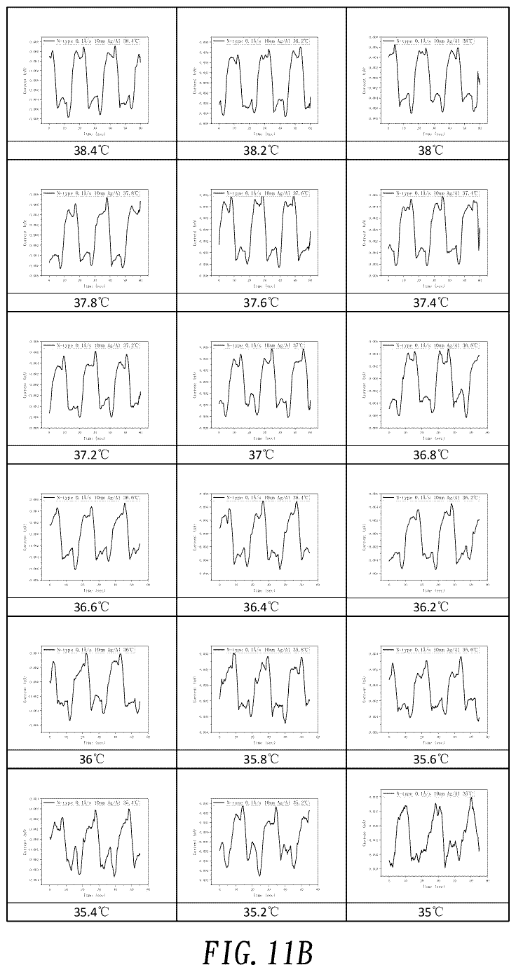

FIGS. 11A and 11B show the fast response converted from the slow response shown in FIGS. 10A and 10B, wherein per 50 data points are taken to convert the measured triangle wave signal into a square wave signal.

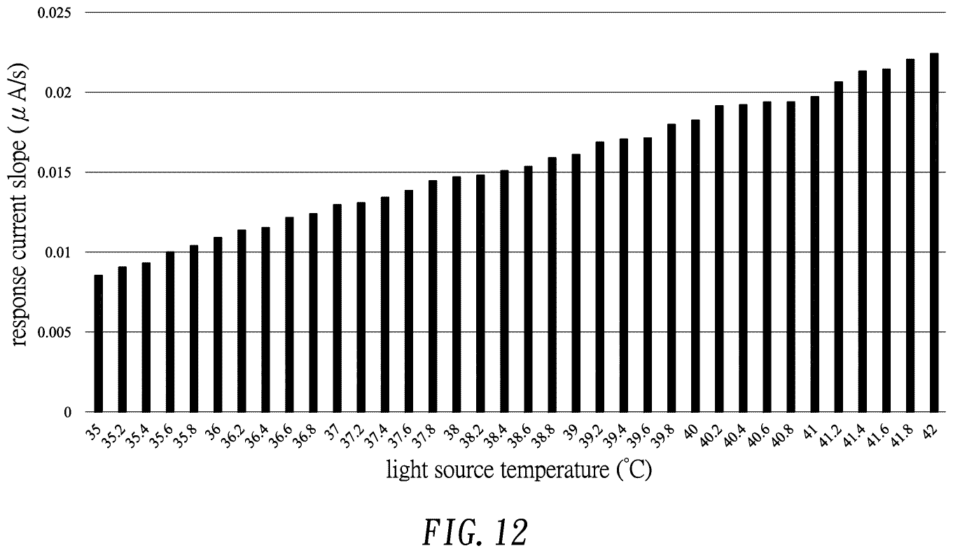

FIG. 12 shows a response current per unit time (response current slope) vs light source temperature bar graph of the photodetector described in FIG. 2B, wherein the photodetector having the inverted pyramid array (IPS) is applied with 0.1 V bias voltage and is 2 cm away from the light source, the chopper has a ON period of 10 second and an OFF period of 10 second, the light source temperature is controlled between 35 to 42 degrees C. with 0.2 degree increment, and per 50 data points are taken to convert the measured triangle wave signal into a square wave signal. The square wave signal alternates between high response current levels and low response current levels, and in the bar graph, the magnitude of response current is obtained by subtracting an average slope of the high response current levels and an average slope of the low response current levels.

As shown in FIG. 12, the response current per unit time (response current slope) of the photodetector having the inverted pyramid array (IPS) decreases as the light source temperature decreases. This demonstrates that the photodetector having the inverted pyramid array (IPS) described in FIG. 2B has a measuring accuracy of 0.2° C.

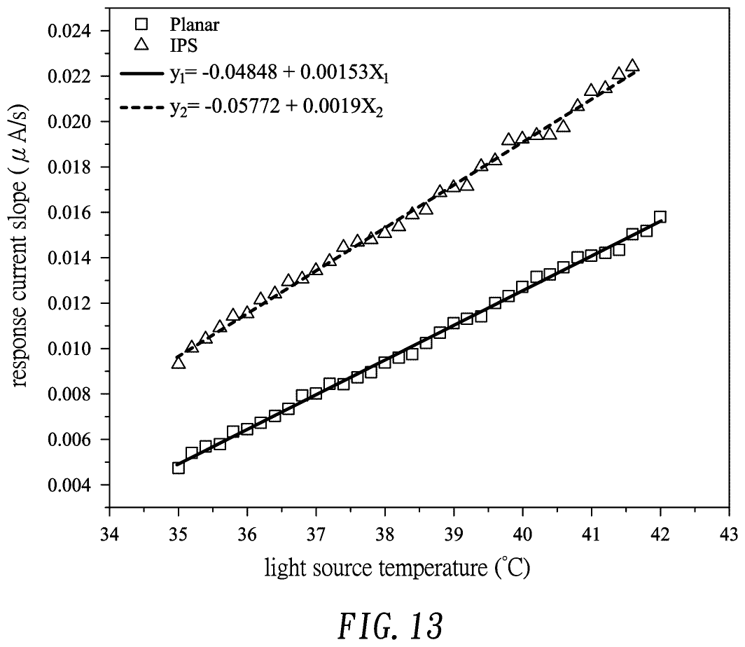

FIG. 13 shows a response current per unit time (response current slope) vs light source temperature scatter plots of the planar photodetector (Planar) and the photodetector having the inverted pyramid array (IPS), wherein the data are taken from FIGS. 9 and 12 and linear fits are performed using a two-variable linear equation. Referring to FIG. 13, the R-squared, also known as the coefficient of determination, of the linear regression for both photodetectors are very close to 1. The response current at higher or lower light source temperatures can be predicted using the linear regression. Notably, the linear fitted slope for the photodetector having inverted pyramid array is greater than that for the planar device.

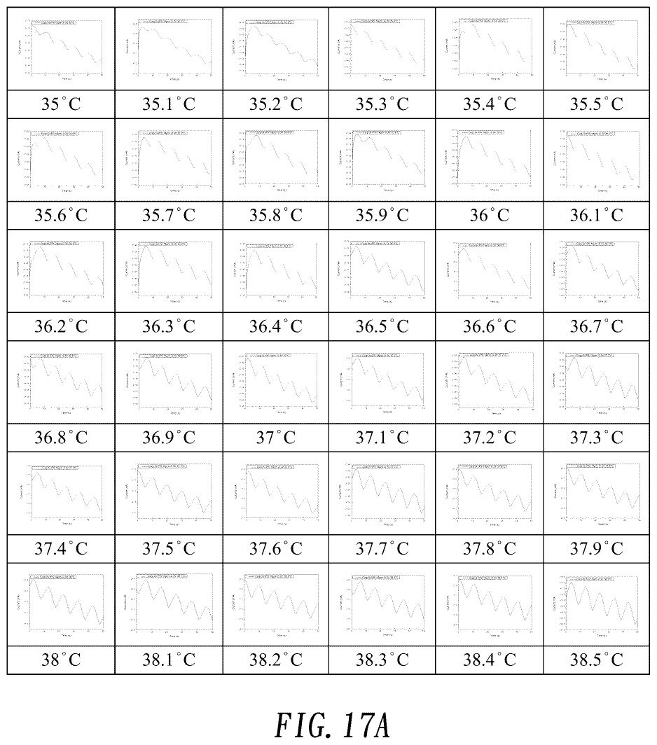

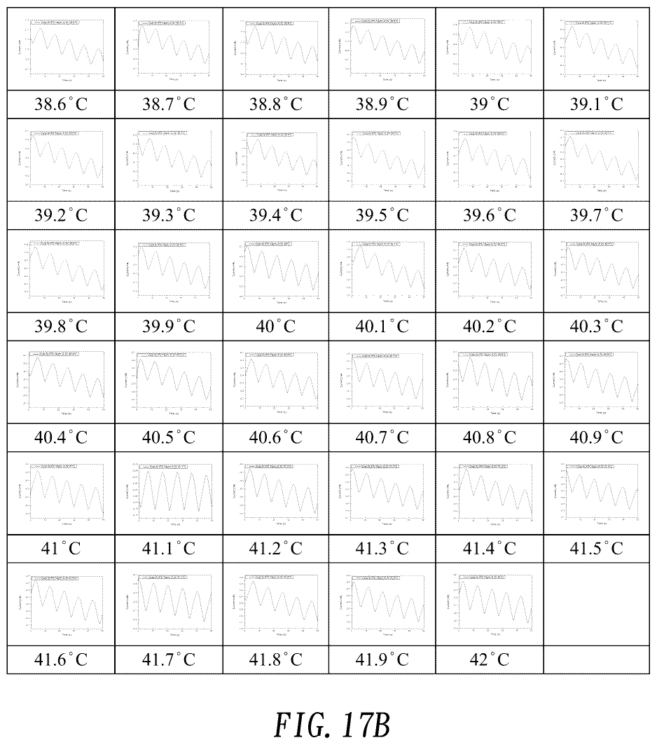

FIGS. 17A and 17B are raw response current vs time (slow response) plots of the photodetector described in FIG. 2B measured at different light source temperatures, wherein the photodetector having the inverted pyramid array (IPS, 14 μm period) is applied with −0.3 V bias voltage and is 2 cm away from the light source, the chopper has a ON period of 10 second and an OFF period of 10 second, and the light source temperature is controlled between 35 to 42 degrees C. with 0.1 degree increment.

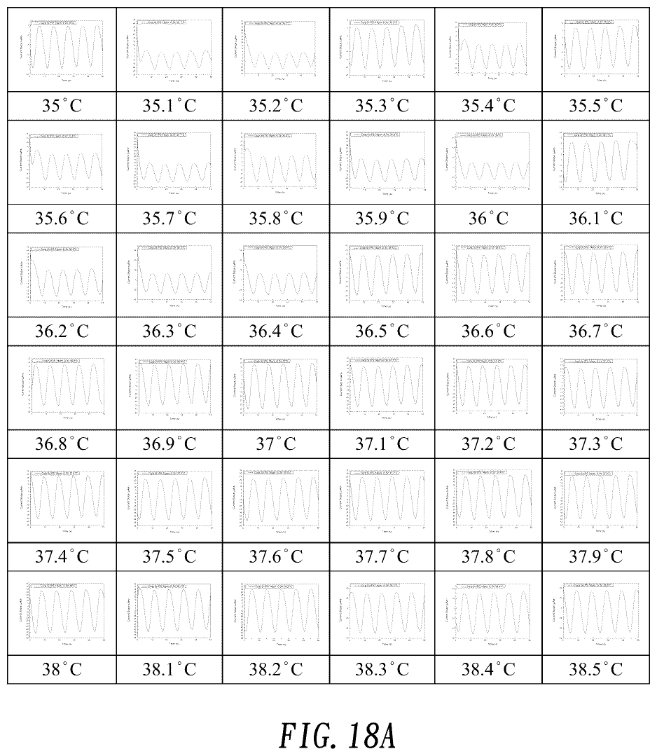

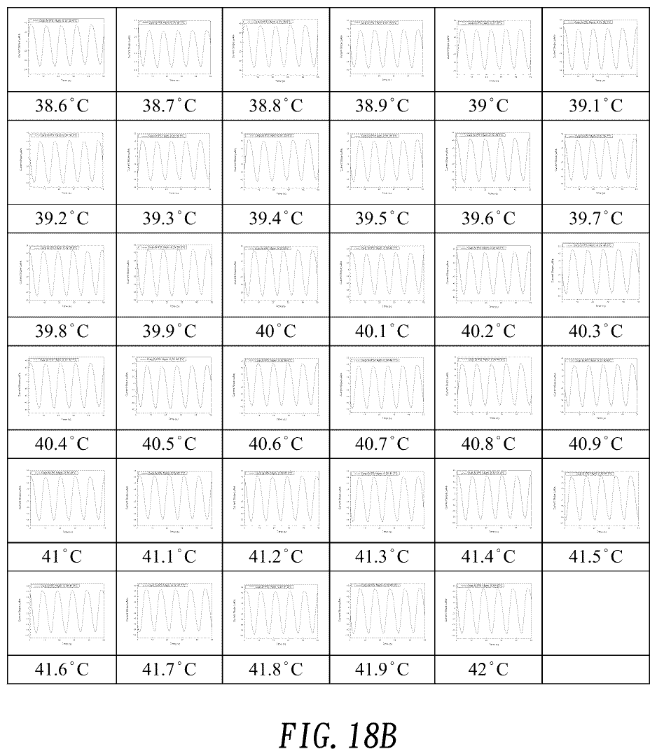

FIGS. 18A and 18B show the fast response converted from the slow response shown in FIGS. 17A and 17B, wherein per 50 data points are taken to convert the measured triangle wave signal into a square wave signal.

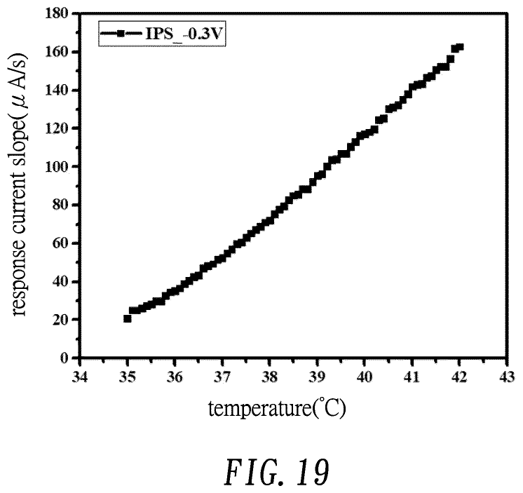

FIG. 19 shows a response current per unit time (response current slope) vs light source temperature line graph of the photodetector described in FIG. 2B, wherein all data are taken from FIGS. 18A and 18B, and in the line graph, the magnitude of response current slope is obtained by subtracting an average slope of the high response current levels and an average slope of the low response current levels.

The results from FIG. 17A-FIG. 19 demonstrate that the provided photodetector has a measurement accuracy of 0.1° C. when reverse biased. Furthermore, the response current (slope) of the reverse biased photodetector is greater than the response current (slope) of the forward biased photodetector.

The experimental results demonstrate that the provided planar and photodetectors with inverted pyramid array can be applied to low-temperature measurement, such as body temperature and blackbody radiation measurement with excellent detection sensitivity and accuracy. Converting slow responses to fast responses improves data comparability and accuracy. In addition, the provided planar photodetectors and photodetectors with inverted pyramid array can measure wavelengths up to mid-infrared band with a cutoff wavelength of 7 microns. They are excellent infrared photodetectors for many fields such as environmental monitoring, night vision, medical diagnosis, and security applications, etc.

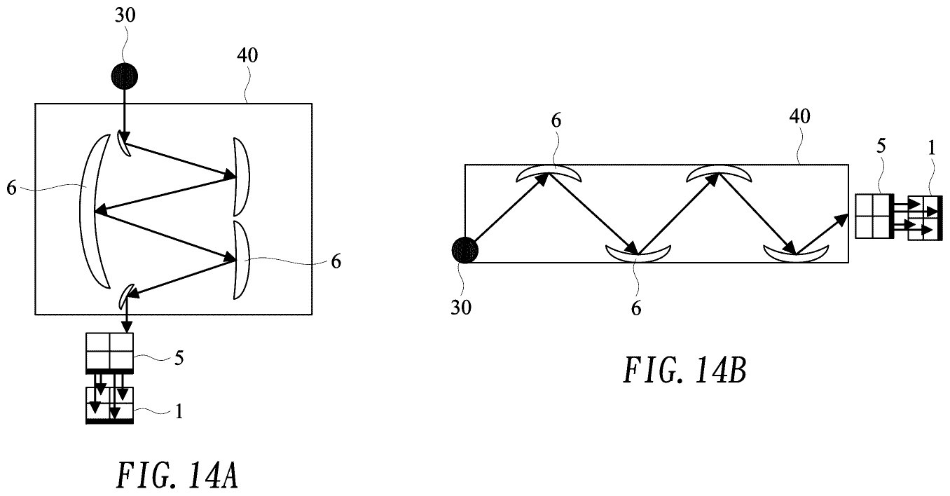

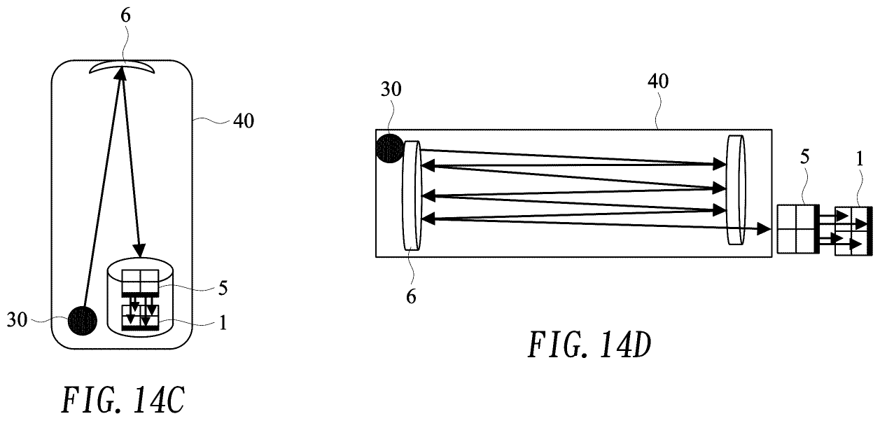

The following embodiments illustrate that the provided photodetector array can be applied, for example, to determine a target component in a gas sample. FIGS. 14A-14D show a detection device composed of an photodetector array for detecting one or more target components in a gas sample according to some embodiments of the present invention. Referring to FIGS. 14A-14D, a light source 30 provides a broad spectrum (wavelength range from near infrared light NIR to mid-infrared light MWIR) infrared radiation to adapt to the characteristic absorption wavelengths of the one or more target components. The light emitted by the light source 30 passes through one or more reflectors/lenses 6 (reflectors and/or lenses 6) and is accurately guided to the area where the gas sample to be detected is located. The reflectors/lenses 6 ensure uniform light distribution, increases the optical path, and maximizes signal sensitivity. The gas sample containing one or more target components, e.g., CO₂ is placed in a sealed gas chamber 40 through which the light passes. The wall of the gas chamber 40 can be transparent and/or at least partially reflective. The target component will absorb or scatter light at a specific wavelength, which is the basis of detection. A filter array 5 is provided behind the gas chamber 40 to separate the light emitted from the light source 30 into light beams of different specific wavelengths, each of which is then directed onto one or more corresponding photodetectors 10 in the photodetector array 1. The filter array 5 may selectively transmit the light in the characteristic absorption wavelengths of the one or more target components to improve detection accuracy. The photodetector array 1 converts each light beam into an electrical signal by one or more photodetectors 10 corresponding to the light beam, thereby determining concentrations of the one or more target components. In the illustrated embodiment, the detection device can be an integrated chip.

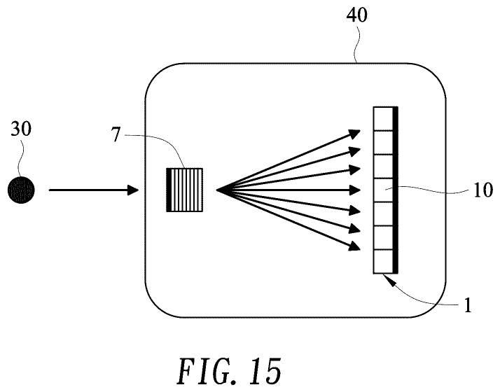

FIG. 15 shows a detection device composed of a photodetector array for detecting one or more target components in a gas sample according to another embodiment of the present invention. Referring to FIG. 15, a light source 30 provides a broad spectrum (wavelength range from near infrared light NIR to mid-infrared light MWIR) infrared radiation to adapt to the characteristic absorption wavelengths of the target components. The broadband light emitted by the light source 30 is separated into multiple monochromatic light beams after passing through a spectrometer 7 (composed of e.g., one or more gratings, mirrors, and/or prisms). The spectrometer 7 accurately separates the light emitted from the light source 30 into multiple monochromatic light beams with each consisting of a single wavelength, providing a basis for subsequent detection. The gas sample containing one or more target components is directed to a sealed gas chamber 40, where the separated light beams interact with the target components. The gas sample containing one or more target components is directed to a sealed gas chamber 40, where the separated light beams interact with the one or more target components. Each target component absorbs a specific amount of the light at its characteristic absorption wavelength, and the degree of absorption reflects the composition and concentration of the target component in the gas sample. Each monochromatic light beam illuminates corresponding one or more photodetectors 10 in the photodetector array 1 to be converted into an electrical signal. These converted electrical signals can be used to calculate the absorption spectrum of the gas sample. In this embodiment, the detection device can be an integrated chip.

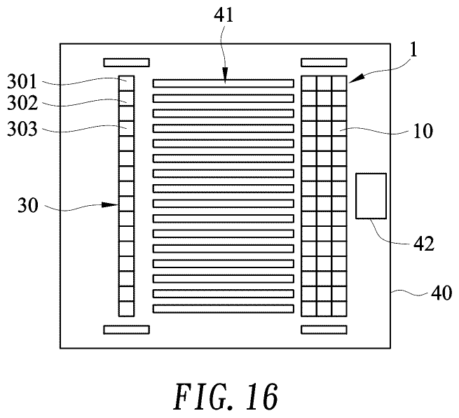

FIG. 16 shows a detection device composed of an photodetector array for detecting one or more target components in a gas sample according to another embodiment of the present invention. In the illustrated embodiment, the detection device can be a multifunctional integrated chip. Referring to FIG. 1, the detection device includes a light source 30, a photodetector array 1, a plurality of waveguide channels 41, an electrical amplifier 42, and a gas chamber 40 containing a gas sample having one or more target components. The light source 30 is a light source array composed of narrowband light sources (301, 302, 303, etc.) that emit multiple monochromatic light beams of different wavelengths to illuminate the gas sample having one or more target components. Each target component absorbs a specific amount of the light at its characteristic absorption wavelength, and each monochromatic light beam passes through a corresponding waveguide optical channels 41 and illuminates corresponding one or more photodetectors 10 in the photodetector array 1. In some embodiments, the waveguide channels 41 may not be required. In some embodiments, the number of target components is plural, and each monochromatic light beams consists of a single wavelength corresponding to a characteristic absorption wavelength of one corresponding target component. In some embodiments, the reference symbol 41 represents independent gas channels rather than waveguide channels. The gas sample containing one or more target components is fluid within each gas channel. The gas channels can be interconnected, while optical paths of the gas channels do not interfere with each other. Each monochromatic light beam emitted by multiple narrowband light sources (301, 302, 303, etc.) passes through the corresponding gas channel and then is converted into electrical signal by the corresponding one or more photodetectors 10 in the photodetector array 1. The detection device may further include an electrical amplifier 42 that connects to the photodetector array 1 and includes a signal processor and communication circuits. In the illustrated embodiment, the front-end (photodetector array), back-end (signal processor and communication circuits), power supply, and other circuits are integrated into a single multifunctional chip using the complementary metal oxide semiconductor (CMOS) process.

Some experimental results discussed above are cited from the inventor Yi-Long Chen's Master Thesis from Graduate Institute of Photonics and Optoelectronics College of Electrical Engineering and Computer Science of National Taiwan University, titled “A Study on the Mid-Infrared Photoelectric Characteristics of Silicon-based Schottky Detectors and the Influence of Metal Film Morphology.” Refer to the above-mentioned thesis for more experimental results, the entire content of which is fully incorporated by reference as if fully set forth herein.

Although the exemplary photodetectors use specific materials, the photodetectors described in FIGS. 2A and 2B could be made of other materials, such as those described in TW patent application Ser. No. 10/711,6340 and application No. 110145523. In one embodiment, the metal layer may be made of gold, silver, copper, chromium, nickel, or a combination thereof.

From the foregoing, it will be appreciated that specific embodiments of the invention have been described herein for purposes of illustration, but that various modifications may be made without deviating from the scope of the invention. Accordingly, the invention is not limited except as by the appended claims.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended.

What is claimed is:

1. A detection device for detecting a light, comprising:
a photodetector array comprising a plurality of photodetectors, each of the plurality of photodetectors comprising:
a semiconductor substrate;
a metal layer, a lower surface of the metal layer forming a Schottky contact with an upper surface of the semiconductor substrate;
a first electrode in contact with an upper surface of the metal layer; and
a second electrode in ohmic contact with a lower surface of the semiconductor substrate;
wherein the photodetector array converts the light into a response signal comprising a photoelectric response signal and/or a photothermal response signal, and the photodetector is locally heated to result in the photothermal response signal if energy of the light is insufficient to cross a Schottky barrier of the photodetector, and wherein the photodetector array further comprises a processor for converting the photothermal response signal into a square wave signal.

2. The detection device according to claim 1, wherein the response signal is a quasi-square wave signal, and the response signal of the photodetector that is reverse biased is greater than the response signal of the photodetector that is forward biased.

3. The detection device according to claim 1, wherein the photothermal response is a triangular wave signal, which is a response current-time signal, and the triangular wave signal is converted into a square wave signal, which is a response current slope-time signal.

4. The detection device according to claim 3, wherein per N data points of the triangular wave signal are subjected to a linear regression to obtain a response current slope, and the obtained response current slopes are plotted against time to obtain the square wave signal, and a fast response slope is obtained based on the square wave signal.

5. The detection device according to claim 4, wherein the square wave signal alternates between high response current slope levels and low response current slopes levels, and the fast response slope is obtained by subtracting an average slope of the high response current slope levels and an average slope of the low response current slope levels.

6. The detection device according to claim 1, wherein the detection device is a thermal imaging device, and the response signal includes a photoelectric response signal and/or a photothermal response signal, wherein the photoelectric response is a square wave signal, which is a response current-time signal, and the photothermal response signal is a triangular wave signal, which is a response current-time signal, and wherein the processor converts the triangular wave signal into a square wave signal, which is a response current slope-time signal, and the processor converts the response current slope-time signal into a temperature signal.

7. The detection device according to claim 6, wherein per N data points of the triangular wave signal are subjected to a linear regression to obtain a response current slope, and the obtained response current slopes are plotted against time to obtain the square wave signal, and a fast response slope is obtained based on the square wave signal.

8. The detection device according to claim 7, wherein the square wave signal alternates between high response current slope levels and low response current slopes levels, and the fast response slope is obtained by subtracting an average slope of the high response current slope levels and an average slope of the low response current slope levels.

9. The detection device according to claim 7, wherein the response current slope-time signal is converted into the temperature signal based on a calibration curve.

10. The detection device according to claim 9, wherein the light is emitted from a light source controlled at a temperature range of 35° C. to 42° C. with increment 0.2° C., the triangular wave signal of the photodetector measured at each temperature is obtained and converted into the square wave signal, and the fast response slope is obtained from the converted square wave signal for each temperature, and wherein the obtained fast response slopes are plotted against the light source temperature to obtain the calibration curve.

11. The detection device according to claim 10, wherein the light source emits the light of wavelengths ranged from 2 μm to 15 μm.

12. The detection device according to claim 10, wherein the temperature of the light source is higher than ambient temperature.

13. The detection device according to claim 10, wherein the temperature of the light source ranges from 30° C. to 200° C.

14. The detection device according to claim 6, wherein an upper surface of the semiconductor substrate comprises an inverted pyramid array.

15. The detection device according to claim 6, wherein the semiconductor substrate is made of silicon, and the metal layer is made of gold, silver, copper, chromium, nickel, or a combination thereof.

16. The detection device according to claim 1, wherein the detection device is used to detect one or more target components in a gas sample, and the detection device further comprises a gas chamber to fluid the gas sample containing the one or more target components, and the light passes through the gas sample and is then converted into an electrical signal by the photodetector array.

17. The detection device according to claim 16, wherein wavelengths of the light range from near-infrared (NIR) band to mid-wave infrared (MWIR) band, and the detection device further comprises a filter array and one or more reflectors and/or lenses, wherein the light passes through the one or more reflectors and/or lenses disposed within the gas chamber, then passes through the filter array, and is then converted into an electrical signal by the photodetector array.

18. The detection device according to claim 16, wherein wavelengths of the light range from near-infrared (NIR) band to mid-wave infrared (MWIR) band, and the detection device further comprises a spectrometer, and wherein the light source passes through the spectrometer disposed within the gas chamber and then is converted into an electrical signal by the photodetector array.

19. The detection device according to claim 16, wherein the light source comprises a plurality of narrowband light sources that emit multiple monochromatic light beams of different wavelengths, each of the multiple monochromatic light beams passes through the gas sample containing the one or more target components and converted into an electrical signal by corresponding one or more photodetectors of the photodetector array.

20. The detection device of claim 19, wherein the gas chamber comprises a plurality of gas channels that are interconnected while optical paths of the plurality of gas channels do not interfere with each other, and each of the multiple monochromatic light beam passes through one corresponding gas channel and then is converted into electrical signal by the corresponding one or more photodetectors in the photodetector array.
